(19) United States
(12) Patent Application Publication
(10) Pub. No.: US 2007/0096170 A1
(43) Pub. Date: May 3, 2007

(54) LOW MODULUS SPACERS FOR CHANNEL STRESS ENHANCEMENT

(75) Inventors: Dureseti Chidambarrao, Weston, CT (US); Henry K. Utomo, Newburgh, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/163,871

(22) Filed: Nov. 2, 2005

(51) Int. Cl. H01L 29/76

(52) U.S. Cl. 257/288

(57) ABSTRACT

A semiconductor structure and its method of fabrication employ a semiconductor substrate having a channel region. A gate electrode is located over the semiconductor substrate. A spacer is located adjacent a sidewall of the gate electrode. The spacer is formed of a material having a modulus of from about 10 to about 50 GPa. The modulus provides enhanced stress within the channel region.

### FIELD OF THE INVENTION

The invention relates generally to physical stress within semiconductor structures. More particularly, the invention relates to physical stress induced charge carrier mobility modification within semiconductor structures such as, for example, metal oxide semiconductor field effect transistors (MOSFETs).

### DESCRIPTION OF THE RELATED ART

Recent advances in semiconductor device design and development have involved the introduction of applied physical stress into semiconductor device components. Applied physical stress often leads to charge carrier mobility modification. In particular, enhanced charge carrier mobility generally leads to enhanced semiconductor device performance.

There are various examples of stress induced performance enhancement within semiconductor devices. For example, Doris et al., in U.S. Pat. No. 6,717,216 teaches a silicon-on-insulator field effect transistor device having a compressive stress in an undercut area to provide increased charge carrier mobility in the device. In addition, Chidambarrao et al., in U.S. Pat. No. 6,825,529 teaches that gate sidewall spacer material may affect tensile or compressive stress within a semiconductor channel region beneath a gate electrode.

Other examples of compressive stress or tensile stress within various locations within semiconductor structures are alternatively known to provide charge carrier mobility modification. Typically, n-FET and p-FET devices respond differently to compressive and tensile stresses since piezoresistance coefficients will typically differ as a function of several variables, including, for instance, semiconductor substrate doping and crystallographic orientation. Thus, stressed components within n-FET and p-FET devices often need to be specifically engineered and optimized.

A trend within semiconductor design and development is for continued enhanced performance at smaller dimensions. Thus, a need will continue to exist for novel structures and methods that form semiconductor devices such as MOSFETs having enhanced performance. To that end, the use of physically stressed structures in semiconductor technology is likely to continue. Desirable are alternative semiconductor structures and methods for fabrication that advantageously employ physical stress for semiconductor device performance enhancement.

### SUMMARY OF THE INVENTION

The present invention provides a semiconductor structure, such as, for example, a MOSFET, having enhanced performance.

The invention also provides a method for readily manufacturing the semiconductor structure.

In accord with the invention, the semiconductor structure comprises a semiconductor substrate having a gate electrode located atop (i.e., over) a surface of the semiconductor substrate and a channel region beneath the gate electrode within the semiconductor substrate. A spacer is formed adjacent to a sidewall of the gate electrode. The spacer is formed of a material having a modulus (Young's modulus) of from about 10 to about 50 gigapascals (GPa). Relative to normal spacer materials this modulus is much lower. This lower modulus spacer allows an enhanced transference of stress from the etch stop nitride liner to the channel. This enhancement is relative to an otherwise analogous structure where a spacer is made of plasma enhanced chemical vapor deposition (PECVD) or rapid thermal chemical vapor deposition (RTCVD) silicon nitride (with modulus typically about 350 GPa) or silicon oxide (with modulus typically about 70 GPa) formed using low temperature oxidation (LTO) or PECVD deposition.

The invention is predicated upon the observation that a spacer having a modulus in the specified range provides enhanced stresses within certain semiconductor structures relative to analogous semiconductor structures having spacers formed of materials (as above) having moduli in a range greater than as taught in the invention (i.e., greater than 50 GPa). Enhanced longitudinal tensile stress and vertical compressive stress are obtained in a channel region of NFETs when tensile etch stop nitride liners are used in combination with low modulus spacers. Enhanced longitudinal compressive stress and vertical tensile stress are obtained in a channel region of PFETs when compressive etch stop nitride liners are used in combination with low modulus spacers. The enhanced stresses, in turn, provide for enhanced charge carrier mobility. The invention is particularly applicable to field effect transistors including n-FETs, p-FETS and a combination thereof.

The invention also provides a comparatively low modulus spacer comprised of a particular silicon oxide material formed utilizing a particular plasma enhanced chemical vapor deposition method. A spacer formed employing the inventive method has a particularly low etch rate when a hydrofluoric acid etchant is employed in fabricating a field effect transistor.

### BRIEF DESCRIPTION OF THE DRAWINGS

FIG. 1, FIG. 2 and FIG. 3 show a series of schematic cross-sectional diagrams illustrating the results of progressive stages in fabricating a field effect transistor in accord with the invention.

FIG. 4 and FIG. 5 show a pair of lateral stress topography graphs for a field effect transistor fabricated not in accord with the invention, and fabricated in accord with the invention.

FIG. 6 and FIG. 7 show a pair of vertical stress topography graphs for a field effect transistor fabricated not in accord with the invention, and fabricated in accord with the invention.

FIG. 8 and FIG. 9 show a pair lateral stress and vertical stress graphs that summarize the stress topography graphs of FIG. 4 to FIG. 7.

### DESCRIPTION OF THE PREFERRED EMBODIMENTS

The invention provides a semiconductor structure and a method for fabricating the semiconductor structure. The semiconductor structure may be fabricated with enhanced performance with respect to charge carrier mobility. The invention realizes the foregoing result by employing a spacer formed adjacent a gate electrode sidewall within the semiconductor structure with a modulus within a specific range. The modulus range is generally low. By “low” it is meant less than about 50 GPa and preferably from about 10 to about 50 GPa. The sidewall spacer having a low modulus provides for enhanced lateral compressive stress and enhanced vertical tensile stress within a channel beneath the gate electrode when used in tandem with highly stressed etch stop nitride liners. When mated with an appropriate semiconductor substrate crystallographic orientation, the spacer assists in providing enhanced charge carrier mobility within the semiconductor structure.

Although the invention is preferably applicable to field effect transistors, the invention is not intended to be so limited. The invention is applicable to any of several semiconductor devices that may employ a gate type electrode or related structure over a channel region within a semiconductor substrate, where the gate has a spacer formed adjacent thereto.

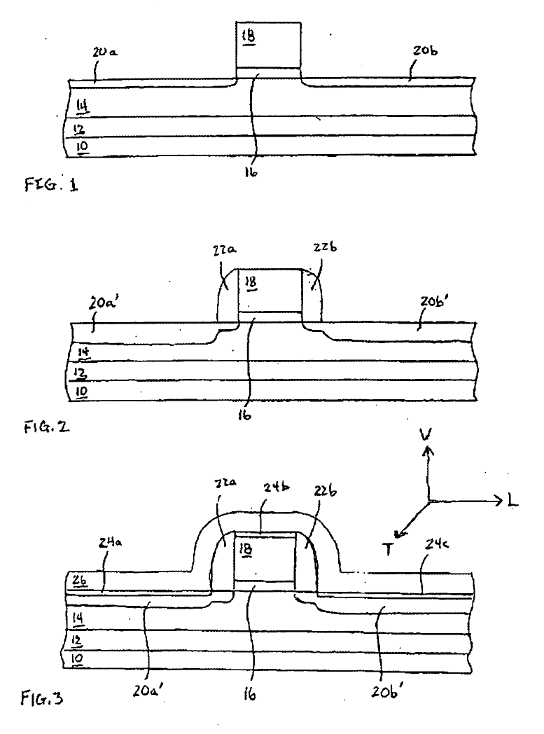

FIG. 1 to FIG. 3 show a series of schematic cross-sectional diagrams illustrating the results of progressive stages in fabricating a field effect transistor in accord with an embodiment of the invention.

FIG. 1 shows a semiconductor substrate 10. A buried insulator layer 12 is located upon the semiconductor substrate 10 and a semiconductor surface layer 14 is in turn located upon the buried insulator layer 12. The buried insulator layer 12 may be a crystalline or non-crystalline oxide or nitride. The substrate including layers 10, 12 and 14 is formed utilizing a conventional process such as, for example, SIMOX (separation by ion implantation of oxygen) or a layer transfer technique.

The structure of the semiconductor substrate 10, buried insulator layer 12 and semiconductor surface layer 14 comprises a semiconductor-on-insulator semiconductor substrate that is typically a silicon semiconductor-on-insulator semiconductor substrate. The invention is not, however, limited to a semiconductor structure formed within a silicon-on-insulator semiconductor substrate. The invention also includes semiconductor devices formed within bulk semiconductor substrates or SiGe-on-insulator substrates. The invention may in general be practiced employing silicon semiconductor substrates, silicon-germanium alloy semiconductor substrates and compound semiconductor substrates.

The invention may be practiced with a bulk silicon semiconductor substrate, a semiconductor-on-insulator semiconductor substrate or a hybrid oriented technology semiconductor substrate that may have at least two surface regions of different crystallographic orientation. Typical crystalline orientations for the silicon semiconductor substrate are (100), (111) and (110). Hybrid substrates may include one surface region having a first crystallographic orientation and a second surface region of a second crystallographic orientation that differs from the first crystallographic orientation.

FIG. 1 also shows a gate dielectric layer 16 located upon the semiconductor surface layer 14 and a gate electrode located upon at least a portion of the gate dielectric layer 16. FIG. 1 finally shows a pair of lightly doped extension regions 20a and 20b located within the semiconductor surface layer 14 and separated by a channel region within the semiconductor surface layer beneath the gate electrode 18.

The gate dielectric layer 16 is typically comprised of an oxide, nitride, oxynitride or combination thereof formed to a thickness from about 10 to about 70 angstroms. Preferably, an oxide having a dielectric constant, as measured in a vacuum, of about 4.0 or greater is employed as the gate dielectric 16. The gate electrode 18 is typically formed of a heavily doped (i.e., 1e20 to 1e21 dopant atoms per cubic centimeter) polysilicon material formed to a thickness from about 1000 to about 3000 angstroms. In addition to doped polysilicon, the gate electrode may also comprise doped poly-SiGe, an elemental conductive metal, an alloy of an elemental conductive metal, a silicide of an elemental conductive metal, a nitride of an elemental conductive metal or any combination thereof, including combinations with doped poly-Si.

The pair of lightly doped extension regions 20a and 20b is formed utilizing a comparatively low dose ion implantation method to provide a dopant of appropriate polarity at a concentration of from about 1e20 to about 5e20 dopant atoms per cubic centimeter. The pair of lightly doped extension regions 20a and 20b may be optional in some embodiments of the invention. An optional halo ion implant may also be used in some embodiments of the invention, although not specifically illustrated in FIG. 1.

FIG. 2 shows a pair of spacers 22a and 22b located adjacent and adjoining the gate electrode 18 and the gate dielectric layer 16. FIG. 2 also shows a pair of source/drain regions 20a′ and 20b′ incorporating the pair of lightly doped extension regions 20a and 20b. They are also located in the semiconductor surface layer 14. The pair of source/drain regions 20a′ and 20b′ continue to bound the channel region beneath the gate electrode 18.

The pair of spacers 22a and 22b is formed of a material that provides in part the subject matter of the invention. Materials constraints when forming the spacers 22a and 22b are disclosed in further detail below.

The pair of source/drain regions 20a and 20b is formed with an appropriate dopant concentration and polarity while employing an additional ion implantation method.

FIG. 3 shows a series of silicide regions 24a, 24b and 24c located upon the source/drain regions 20a and 20b and the gate electrode 18. FIG. 3 also shows an etch stop liner layer 26 that covers the field effect transistor.

The series of silicide layers 24a, 24b and 24c is formed utilizing a conventional self-aligned (i.e., salicidation) process to yield a silicide material formed to a thickness from about 50 to about 300 angstroms. The series of silicide layers 24a, 24b and 24c assists in providing enhanced conductivity to the source/drain regions 20a and 20b and the gate electrode 18. Typically, such silicide materials may include, but are not limited to, titanium silicides, platinum silicides, nickel silicides, cobalt silicides, and other alloy combinations.

Although a silicide is shown atop the gate electrode 18, the present invention also contemplates embodiments in which the silicide is not located atop the gate electrode 18. In such embodiments, a dielectric cap is present atop the gate electrode 18 during the salicidation process.

Finally, the etch stop liner layer 26 is typically formed of a silicon nitride material or other etch stop dielectric material formed to a thickness from about 300 to about 2000 angstroms. The intrinsic stress in this liner can be varied to be as high as 2 GPa for tensile applications on the NFET and −3.5 to −4 GPa for compressive applications for PFETs.

FIG. 3 finally shows crystallographic orientation reference axes for the field effect transistor. When formed utilizing a (001) oriented substrate, crystallographic orientation planes are L=(110), T=(1-10) and V=(001). When formed utilizing a (110) oriented substrate, crystallographic orientation planes are L=(110), T=(001) and V=(1-10).

The invention is directed towards the influence of materials properties of the pair of spacers 22a and 22b upon charge carrier mobility within the channel region beneath the gate electrode 18. To that end, the invention provides that the pair of spacers 22a and 22b comprises a comparatively soft material having a modulus preferably from about 10 to about 50 GPa, more preferably from about 10 to about 25 GPa and most preferably from about 15 to about 20 GPa. As will be shown in the series of stress topography graphs that follows, a softness (lower modulus material being softer relative to higher modulus material) in the foregoing ranges provides for enhanced charge carrier mobility performance of a field effect transistor when fabricated upon a particular silicon semiconductor substrate crystallographic orientation.

The invention does not specifically limit the type of materials that may be employed for forming the spacer having the modulus of from about 10 to about 50 GPa. From a practical point of view, any of several materials may be employed, including conductor materials, semiconductor materials and dielectric materials. A silicon oxide dielectric material is desirable. An undoped silicon oxide dielectric material formed employing a plasma enhanced chemical vapor deposition method is also desirable. Such a method may employ: (1) silane and nitrous oxide as silicon and oxygen source materials; (2) carrier gases such as nitrogen, helium or hydrogen; (3) a deposition pressure of less than 10 torr and more preferable less than 1 torr; (4) a deposition rate of from about 5 to about 25 angstroms per second and more preferably from about 10 to about 20 angstroms per second; and (5) a deposition temperature of from about 400° to about 480° C. and more preferably from about 430° to about 450° C.

The foregoing limitations are desirable for forming the undoped silicon oxide material from which is formed the spacers 22a and 22b. When employing those limitations, the invention provides spacers 22a and 22b with a particularly low etch rate in a hydrofluoric acid etchant. The etch rate may be on the order of only about twice that of a thermal oxide etch rate and on the order of one fifth of other chemical vapor deposition deposited silicon oxide etch rates. Under these circumstances, a pre-salicidation hydrofluoric acid clean of a semiconductor structure may be effected while minimally etching the pair of spacers 22a and 22b.

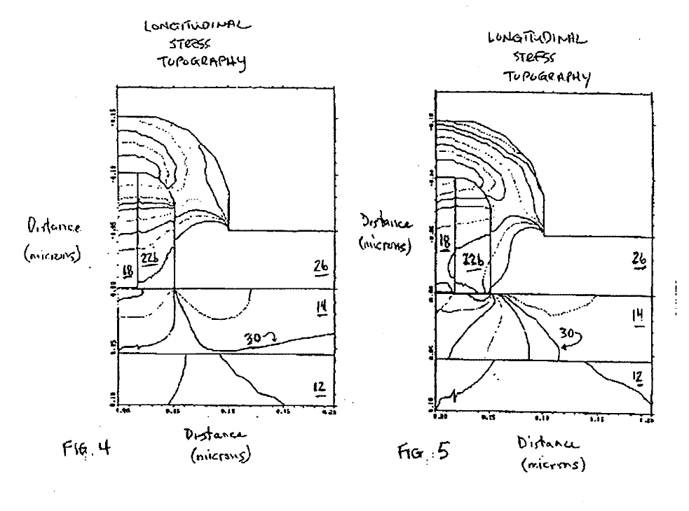

FIG. 4 shows a longitudinal stress topography graph for a field effect transistor not in accord with the invention. The field effect transistor is fabricated within a silicon-on-insulator (SOI) semiconductor substrate.

FIG. 4 shows the buried oxide layer 12. The silicon surface layer 14 is located upon the buried oxide layer 12. The gate electrode 18 is located over the silicon surface layer 14. The spacer 22b adjoins the gate electrode 18. Finally, the etch stop liner layer 26 is formed covering the gate electrode 18, the spacer 22b and exposed portions of the silicon surface layer 14.

The stress topography graph as illustrated in FIG. 4 is calculated employing the following values for modulus for various components: (1) spacer 22b is comprised of oxide and nitride materials which have moduli of 70 GPa and 350 GPa, respectively, and nitride etch stop liner layer 26 is assumed to have a modulus of 350 GPa (and the etch stop liner layer 26 is initially deposited with an intrinsic compressive stress of about −2 GPa); (2) gate electrode 18 and the silicon surface layer 14 are assumed to have a modulus of 150 GPa; and (3) gate dielectric layer 16 (reference numeral omitted for clarity, but minimally shown as darkened line beneath gate 18) is assumed to have a modulus of 70 GPa. The compressive stress nitride etch stop liner 26 is used over PFETs. The stress values are reversed when tensile nitride liners are used over the NFETs.

FIG. 4 shows a zero stress line 30 within the silicon surface layer 14. To the right of the zero stress line 30 is a single tensile stress topography line at 50 MPa tensile stress. To the left of the zero stress line 30 is a series of three compressive stress lines increasing at −50 MPa compressive stress intervals and terminating with −150 MPa compressive stress beneath the gate electrode 18.

FIG. 5 shows a stress topography graph corresponding with the stress topography graph of FIG. 4, but with the exception that the calculation algorithm employs a modulus for the spacer 22b of 20 GPa (within the range of the present invention) rather than a stack comprising materials of silicon oxide with modulus of 70 GPa and nitride with modulus of 350 GPa. As illustrated in FIG. 5, reference numeral 30 still corresponds with a zero stress line within the silicon surface layer 14. To the right of reference numeral 30 is a single tensile stress contour line at 50 MPa tensile stress. To the left of reference numeral 30 is a series of five stress contour lines that end yielding −250 MPa compressive stress within the channel region beneath the gate electrode 18. Again this is for PFETs.

Thus, as is seen by the comparison of FIG. 4 and FIG. 5, the use of a spacer of a generally lower modulus of about 20 GPa in comparison with a higher modulus stack of oxide with modulus of 70 GPa and a nitride of about 350 GPa yields higher compressive stresses in a longitudinal direction in a channel region of a field effect transistor.

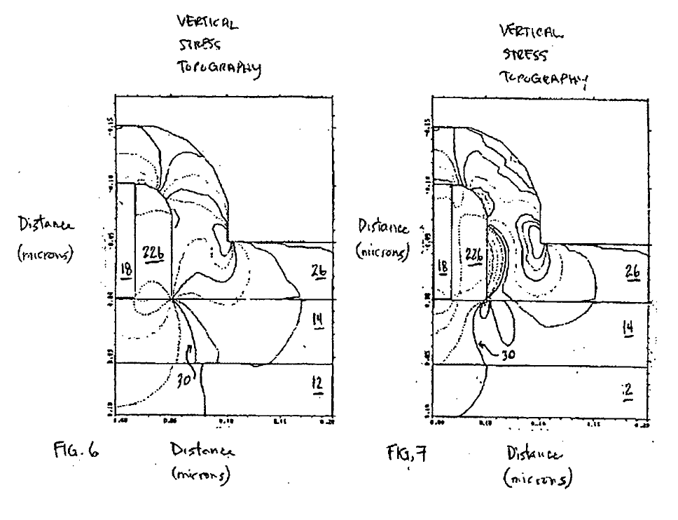

FIG. 6 and FIG. 7 show a pair of stress topography diagrams corresponding with the stress topography diagrams of FIG. 4 and FIG. 5, but for stress in a vertical direction rather than a longitudinal direction. Similarly with FIG. 4 and FIG. 5, both FIG. 6 and FIG. 7 illustrate a zero stress line 30 within the silicon surface layer 14. To the left of the zero stress line 30 are tensile stress contours and to the right of the zero stress line 30 are compressive stress contours. FIG. 6 corresponds with FIG. 4 insofar as the spacer 22b is formed of a material having an enhanced hardness and a stack with oxide with modulus of 70 GPa and silicon nitride with modulus of 350 GPa. FIG. 7 corresponds with FIG. 5 insofar as the spacer 22b is formed of a material having a decreased hardness and a modulus of 20 GPa.

As seen from comparison of FIG. 6 and FIG. 7, there is an additional tensile stress contour line within the channel region beneath the gate electrode 18 within FIG. 7 having the comparatively soft spacer 22b of modulus about 20 GPa. Thus, the semiconductor structure of FIG. 7 has enhanced tensile vertical stress that may provide enhanced charge carrier mobility for a semiconductor substrate of certain crystallographic orientation and dopant polarity.

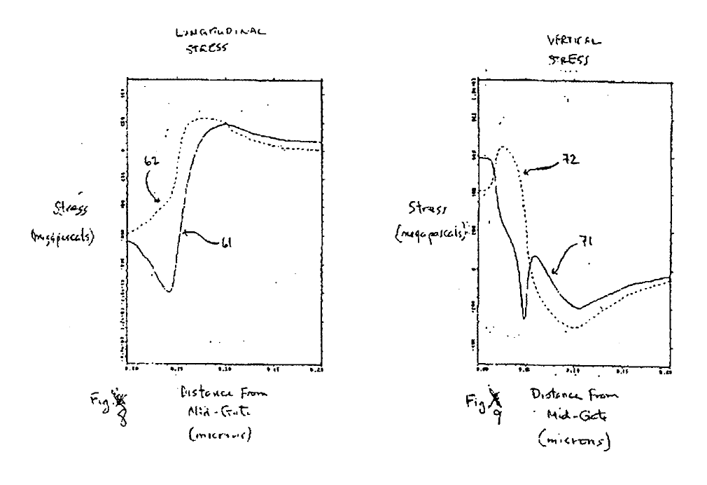

FIG. 8 and FIG. 9 summarize the stress information illustrated in the stress topography graphs of FIGS. 4-7.

Within FIG. 8 reference numeral 61 corresponds with a longitudinal stress profile for a field effect transistor fabricated with a 20 GPa modulus spacer. Reference numeral 62 corresponds with a longitudinal stress profile for a field effect transistor fabricated with a spacer with a combined oxide/nitride stack with 70/350 GPa modulus. As is seen in FIG. 8, the low modulus spacer provides greater compressive stress within a channel region that typically has a distance of about 0.02 microns from a mid-gate electrode dimension.

Within FIG. 9, reference numeral 71 corresponds with a vertical stress profile for a field effect transistor fabricated with a 20 GPa modulus spacer. Reference numeral 72 corresponds with a vertical stress profile for a field effect transistor fabricated with a spacer with a combined oxide nitride stack with 70/350 GPa modulus. As is seen in FIG. 9, the channel region of the field effect transistor fabricated within the low modulus spacer has a higher tensile stress.

Piezoresistance coefficients for (001) silicon in the order of longitudinal, transverse and vertical directions for n and p polarities are as follows (units are 1e-11/pascal): (1) for n silicon, −31.6, −17.6 and 53.4; (2) for p silicon, 71.8, −1.1 and −66.3. Piezoresistance coefficients for (110) p silicon are 71.8, −66.3 and −1.1. Crystallographic orientation (001) silicon is typically bulk silicon. Crystallographic orientation (110) silicon typically derives from a silicon-on-insulator semiconductor substrate. Charge carrier mobility enhancements are typically calculated as a summary of piezoresistance coefficient times applied stress, and summed for each of the longitudinal, vertical and transverse directions.

As a consequence of dimensionally appropriate enhanced stress within channel regions, the invention provides an opportunity for charge carrier mobility improvement within both n-FET and p-FET devices. A longitudinal compressive stress is advantageous to a p-FET device whether fabricated on a (001) silicon semiconductor substrate or a (110) silicon semiconductor substrate. A vertical tensile stress is advantageous to a p-FET fabricated on a (110) silicon semiconductor substrate or an n-FET fabricated on a (001) silicon semiconductor substrate.

There are several calculation algorithms that may be employed to approximate charge carrier mobility gains for field effect transistors in accord with an embodiment of the invention. As an approximate summary with respect to low modulus spacers in comparison with high modulus spacers, an n-FET is expected to have about a 16 percent charge carrier mobility enhancement and a p-FET is expected to have about a 20 percent charge carrier mobility enhancement. In addition, p-FET transistors have added charge carrier mobility advantages when formed on (110) silicon surfaces in comparison with (001) silicon surfaces.

The preferred embodiment of the invention is illustrative of the invention rather than limiting of the invention. Revisions and modifications may be made to methods, materials, structures and dimensions in accord with the preferred embodiment of the invention while still providing an embodiment in accord with the invention, further in accord with the accompanying claims.

What is claimed is:

1. A semiconductor structure comprising:
a semiconductor substrate comprising a channel region;
a gate electrode located over the semiconductor substrate atop the channel region; and
a spacer adjacent to a sidewall of the gate electrode, where the spacer is formed of a material having a modulus from about 10 to about 50 GPa.

2. The structure of claim 1 wherein the spacer is comprised of a dielectric material.

3. The structure of claim 1 wherein the spacer is comprised of a conductor material.

4. The structure of claim 1 wherein the gate electrode is a component of a field effect transistor.

5. The structure of claim 1 wherein the spacer is comprised of a material having a modulus from about 10 to about 25 GPa.

6. The device of claim 1 wherein the spacer is comprised of a material having a modulus from about 15 to about 20 GPa.

7. A method for fabricating a semiconductor structure comprising:
forming a gate electrode over a semiconductor substrate, the semiconductor substrate including a channel region; and
forming a spacer adjacent to a sidewall of the gate electrode, where the spacer is formed of a material having a modulus from about 10 to about 50 GPa.

8. The method of claim 7 wherein the spacer is comprised of a dielectric material.

9. The method of claim 7 wherein the gate electrode is a component of a field effect transistor.

10. The method of claim 7 wherein the spacer is comprised of a material having a modulus of from about 10 to about 25 GPa.

11. The method of claim 7 wherein the spacer is comprised of a material having a modulus from about 15 to about 20 GPa.

12. A method for fabricating a semiconductor structure comprising:
forming a gate electrode over a semiconductor substrate, the semiconductor substrate having a channel region; and
forming a spacer adjacent to a sidewall of the gate electrode, where the spacer is formed of a silicon oxide material having a modulus from about 10 to about 50 GPa.

13. The method of claim 12 wherein the silicon oxide material is formed employing a plasma enhanced chemical vapor deposition method.

14. The method of claim 13 wherein the plasma enhanced chemical vapor deposition method employs silane as a silicon source material and nitrous oxide as an oxidant source material.

15. The method of claim 13 wherein the plasma enhanced chemical vapor deposition method employs a deposition temperature from about 400° to about 480° C.

16. The method of claim 13 wherein the plasma enhanced chemical vapor deposition method employs a deposition rate from about 5 to about 25 angstroms per second.

17. The method of claim 12 wherein the silicon oxide material has a modulus from about 10 to about 25 GPa.

18. The method of claim 12 wherein the silicon oxide material has a modulus from about 15 to about 20 GPa.
